(19) United States
(12) Patent Application Publication
(10) Pub. No.: US 2025/0386742 A1
(43) Pub. Date: Dec. 18, 2025

(54) ASYMMETRIC JOSEPHSON JUNCTIONS FOR SUPPRESSION OF CORRELATED ERRORS IN SUPERCONDUCTING QUBITS

(71) Applicant: Massachusetts Institute of Technology, Cambridge, MA (US)

(72) Inventors: Patrick Harrington, Reading, MA (US); Willam Oliver, Lexington, MA (US); Kyle Serniak, Somerville, MA (US)

(21) Appl. No.: 18/542,453

(22) Filed: Dec. 15, 2023

Related U.S. Application Data
(60) Provisional application No. 63/446,190, filed on Feb. 16, 2023.

(51) Int. Cl. H10N 60/12; G06N 10/40; H10N 60/01; H10N 60/80

(52) U.S. Cl. CPC H10N 60/12; G06N 10/40; H10N 60/805; H10N 60/0912

(57) ABSTRACT

A unit of quantum information comprises a first electrode having a first thickness and providing a first superconducting gap energy at a first region of a substrate, a second electrode a second thickness that is greater than the first thickness and providing a second superconducting gap energy at a second region of the substrate that is less than the first superconducting gap energy, a barrier that separates the first region and the second region, and an asymmetric junction at the, the asymmetric junction having a low superconducting energy gap region at the second region; and a low superconducting energy gap region at the first region. The asymmetric junction is oriented so that the second electrode is a lower gap electrode having a larger external source of quasiparticles than the first electrode that can otherwise induce correlated errors to block or reduce a first tunneling rate of quasiparticles from the second region through the barrier to the first region as compared to a second tunneling rate of quasiparticles from the first region through the barrier to the second region.

### RELATED APPLICATIONS

This application claims the benefit of the earlier filing date of U.S. Provisional Patent Application No. 63/446,190, filed February 16, 2023, and entitled “Asymmetric Josephson Junctions for Suppression of Correlated Errors in Superconducting Qubits,” the entirety of which is incorporated herein by reference.

### GOVERNMENT RIGHTS IN THE INVENTION

This invention was made with government support under FA8702-15-D-0001 awarded by the U.S. Air Force. The government has certain rights in the invention."

### FIELD OF THE INVENTION

The present invention relates generally to quantum computing, and more specifically to a computing device that mitigates quasiparticle-related correlated errors of superconducting qubits that may originate from energy deposited to a superconducting device substrate by ionizing radiation.

### BACKGROUND OF THE INVENTION

Quantum computers rely on the properties of quantum physics to store data and perform computations at scales and speeds substantially greater than conventional digital computers. For example, digital computers operate on binary data, or bits, each having a 1 value or a 0 value. Quantum computers, on the other hand, implement quantum bits, or qubits, which unlike bits, can have multiple states at the same time, referred to as superposition. Accordingly, a qubit can have a 0 value and a 1 value simultaneously, allowing a quantum computer to process data much faster than classical computers. Another important and unique characteristic is that qubits can be entangled to each other such that measuring the value of one can influence the value of another. Entangled qubits store all the possible combinations of the quantum states of each qubit (e.g., for two qubits, this results in four values).

Qubits, however, may be prone to errors such as phase flips and bit flips, where a quantum superposition state changes. Correlated errors that happen simultaneously across neighboring qubits are particularly undesirable. Uncorrelated errors, on the other hand, are acceptable because they generally can be addressed by quantum error correction protocols if the errors are sufficiently sparse. For superconducting qubits, high-energy particle impacts from ionizing radiation produces energetic phonons that travel throughout the substrate and create excitations above the superconducting ground state, known as quasiparticle excitations (QPs), which can inhibit the performance of a multi-qubit device by generating correlated errors across a multiqubit array. Such correlated errors challenge conventional error correction schemes and the feasibility of fault-tolerant quantum computing technologies.

### SUMMARY

In one aspect, provided is an arrangement of superconductive circuitry in a quantum computing device, the computational accuracy of which is degraded by quasiparticle-induced spatially and/or temporally correlated errors, each superconductive circuit in the arrangement comprising: a first electrode deposited on a substrate, the first electrode constructed and arranged to provide a first superconducting gap energy at a first region of the substrate; a second electrode deposited on the substrate, the second electrode constructed and arranged to provide a second superconducting gap energy at a second region of the substrate that is less than the first superconducting gap energy at the first region; a barrier that separates the first region and the second region; and an asymmetric junction at the barrier. The asymmetric junction is formed by an energy gap difference between the first superconducting gap energy of the first electrode and the second superconducting gap energy of the second electrode. The asymmetric junction is oriented so that the second electrode is a lower gap electrode having a larger source of quasiparticles than the first electrode to block or reduce a first tunneling rate of quasiparticles from the second region through the barrier to the first region as compared to a second tunneling rate of quasiparticles from the first region through the barrier to the second region.

In some embodiments, the asymmetric junction operates as a Josephson junction to prevent quasiparticle tunneling related to a spatiotemporally correlated error burst at the quantum computing device.

In some embodiments, the arrangement of quantum information may further comprise a ground plane above the substrate, wherein the second electrode includes a lower gap electrode that is galvanically connected to the ground plane.

In some embodiments, the arrangement of quantum information may further comprise multiple asymmetric junctions to reduce quasiparticle tunneling in one direction from the ground plane across the junctions to a capacitor, and in another direction from the capacitor across the junctions to the ground plane.

In some embodiments, the arrangement of quantum information may further comprise one or more quasiparticle blocking structures unattached to at least one qubit of the superconducting qubits so that a quasiparticle blocking effect can be realized without a qubit.

In some embodiments, a thickness of the first and/or second electrode may be controlled by a deposition rate or deposition duration.

In some embodiments, a superconducting gap energy difference between the first superconducting gap energy and the second superconducting gap energy may be greater than a qubit transition frequency at the insulating barrier.

In some embodiments, the first and second electrodes may be formed of different superconducting materials.

In some embodiments, the asymmetric junction is oriented so that the second electrode is a lower gap electrode having a majority of quasiparticles as compared to the first electrode.

In some embodiments, a gap energy difference between the first and second electrodes is greater than an energy of the quasiparticles at the asymmetric junction.

In another aspect, provided is a quantum computing device, the computational accuracy of which is degraded by quasiparticle-induced spatiotemporally correlated qubit error comprising a substrate and an arrangement of units of quantum information, wherein each unit of quantum information comprises: a first electrode on the substrate, the first electrode constructed and arranged to provide a first superconducting gap energy at a first region of the substrate; a second electrode on the substrate, the second electrode constructed and arranged to provide a second superconducting gap energy at a second region of the substrate that is less than the first superconducting gap energy at the first region; a barrier that separates the first region and the second region; and an asymmetric junction at the barrier, the asymmetric junction formed by an energy gap difference between the first superconducting gap energy of the first electrode and the second superconducting gap energy of the second electrode, the asymmetric junction oriented so that the second electrode is a lower gap electrode having a larger external source of quasiparticles than the first electrode to block or reduce a first tunneling rate of quasiparticles from the second region through the barrier to the first region as compared to a second tunneling rate of quasiparticles from the first region through the barrier to the second region.

In another aspect, provided is a method for operating a quantum computing device, the computational accuracy of which is degraded by quasiparticle-induced spatiotemporally correlated qubit error comprising: arranging superconductive circuitry on a substrate, wherein for each superconductive circuit. The method comprises: depositing a first electrode on the substrate, the first electrode constructed and arranged to provide a first superconducting gap energy at a first region of the substrate; depositing a second electrode on the substrate, the second electrode constructed and arranged to provide a second superconducting gap energy at a second region of the substrate that is less than the first superconducting gap energy at the first region; forming a barrier that separates the first region and the second region; forming the asymmetric junction formed by an energy gap difference between the first superconducting gap energy of the first electrode and the second superconducting gap energy of the second electrode; and orienting so that the second electrode is a lower gap electrode having a larger external source of quasiparticles than the first electrode to block or reduce a first tunneling rate of quasiparticles from the second region through the barrier to the first region as compared to a second tunneling rate of quasiparticles from the first region through the barrier to the second region.

In another aspect, an integration of asymmetric junctions and quasiparticle trapping technique includes a preferred asymmetric junction orientation that may be provided in the presence of quasiparticle trapping effects, such that trapping effects reduce a source of quasiparticles from a region of the device. Trapping effects may be intentional or unintentional due to presence of materials that may have trapping effects, e.g. air bridges, bump bonds, wirebonds, which otherwise have another function.

One method to orient an asymmetric junction according to some embodiments is to implement quasiparticle trapping in one region (i.e. ground plane) such that the other region is a significant source of quasiparticles. The junction is then oriented according so that a second electrode is a lower gap electrode having a larger source of quasiparticles than a first electrode to block or reduce a first tunneling rate of quasiparticles from a second region at or near the second electrode through the barrier to the first region as compared to a second tunneling rate of quasiparticles from a first region at or near the first electrode through the barrier to the second region.

Another method to orient an asymmetric junction according to some embodiments is to implement quasiparticle trapping in a region using the higher-gap electrode itself. Quasiparticles may not enter the higher-gap electrode if the superconducting gap of the electrode exceeds the gap of the region to which it is connected (and the characteristic energy of the quasiparticles in that region). In this case, the asymmetric junction is oriented such that quasiparticles are trapped in one region away from the junction and quasiparticle tunneling is also prevented from a region connected to the lower-gap electrode (due to the superconducting gap asymmetry of junction electrodes described herein. This method may be used if electrodes are connected to similarly significant sources of quasiparticles, such as in the case of a differential capacitance circuit geometry.

### BRIEF DESCRIPTION OF THE DRAWINGS

The above and further advantages of this invention may be better understood by referring to the following description in conjunction with the accompanying drawings, in which like numerals indicate like structural elements and features in the various figures. For clarity, not every element may be labeled in every figure. The drawings are not necessarily to scale, emphasis instead being placed upon showing the principles of the invention.

FIG. 1 depicts a top view representation of undesirable quasiparticle tunnelling across a Josephson junction of a multiqubit chip.

FIGS. 2A-2C depict an example Josephson junction film deposition process, in accordance with the present disclosure.

FIG. 3 depicts an example of a method for achieving quasiparticle blocking, in accordance with the present disclosure.

FIG. 4 depicts an example of quasiparticle tunneling in a superconducting circuit, in accordance with the present disclosure.

FIG. 5 depicts an example of an asymmetric junction, in accordance with some embodiments.

### DETAILED DESCRIPTION

Undesirable correlated errors can occur in a multiqubit chip when ionizing radiation provides energy at a superconducting substrate, e.g. silicon, sapphire, and so on, of the chip. For example, performance tests have established that approximately 1 MeV of energy may be deposited rapidly, e.g., ~1 ns. The high-energy particle impacts from low-level radioactivity and cosmic ray muons can ionize atoms in the substrate and result in the formation of phonons that travel throughout the chip and generate quasiparticle excitations above the superconducting ground state, which can inhibit the performance of many qubits on the chip simultaneously over a duration on the order of milliseconds or less. Quasiparticles diffusing throughout the chip may tunnel through the Josephson junctions of multiple individual qubits. Individual qubit errors occur if a quasiparticle tunnels across the Josephson junction and causes a relaxation or excitation transition of the qubit’s state. If individual qubits are susceptible to quasiparticle tunneling, then ionizing radiation impacts may cause spatiotemporally correlated, or effectively simultaneous, errors of multiple qubits.

The techniques and features described in the present disclosure provide an improvement to existing design and fabrication techniques that construct a Josephson junction to control the tunneling of quasiparticles, namely, by prescribing a superconducting gap engineering technique for the junction electrodes of each individual qubit so as to mitigate qubit errors that are correlated in space and/or time.

The mitigation of quasiparticle tunneling in a superconducting circuit with a Josephson junction may be performed by applying a conventional “quasiparticle trapping” technique. Quasiparticle trapping is achieved by adding low energy gap superconductors or normal metal materials to the qubit construction. These materials can “trap” quasiparticles, and thereby funnel quasiparticles away from the Josephson junction before quasiparticles tunneling can be attempted. Related techniques may prevent quasiparticle generation by structures that trap and downconvert phonons, which can generate quasiparticles in aluminum components of a quantum chip. Accordingly, these conventional techniques may use quasiparticle trapping regions having lower gap energies than the higher gap energy electrodes to remove quasiparticles that would otherwise tunnel across the junction between the two electrodes.

Embodiments of the present inventive concepts provide an improvement by employing superconducting gap engineering of the junction electrodes to avoid spatially correlated errors of superconducting qubits caused from ionizing radiation or other sources of energy deposition to a quantum device. In contrast to a trapping technique, embodiments of the techniques and features described in the present disclosure utilize a quasiparticle blocking method applied to the Josephson junctions of individual qubits, which are superconducting devices comprising an insulator, semiconductor, or other transmissive barrier separating two superconducting regions. Here, the superconducting gap energy of one or more junction electrodes is varied to prevent quasiparticle tunneling through the Josephson junction barrier, which achieves quasiparticle blocking. Accordingly, in contrast to quasiparticle trapping techniques, the present invention can reduce correlated qubit errors by suppressing the tunneling of quasiparticles through the qubit’s junction instead of funneling quasiparticles away from the Josephson junction before quasiparticles tunneling can be attempted. This is achieved by the application of different superconducting gap energies for the electrodes themselves, thereby providing an asymmetric junction instead of the use of higher gap energies of the junction relative to the trapping regions used in trapping techniques. The reduced sensitivity of superconducting qubits to the quasiparticles created by ionizing radiation can result in the reduction of spatiotemporally correlated errors. For example, spatiotemporally correlated, e.g., 0-10 ms and/or 0-1 cm, qubit errors from quasiparticle tunneling can be mitigated, which can be beneficial for quantum error correction. In some embodiments, a junction is not part of a qubit, but is a part of other circuitry, related to the operation of qubits and/or a quantum computing device. Quasiparticle blocking can be achieved between the ground plane and a qubit's electrodes if an asymmetric junction is formed between the ground plane and an electrode. This may constitute an optional trapping function that complements the abovementioned blocking technique.

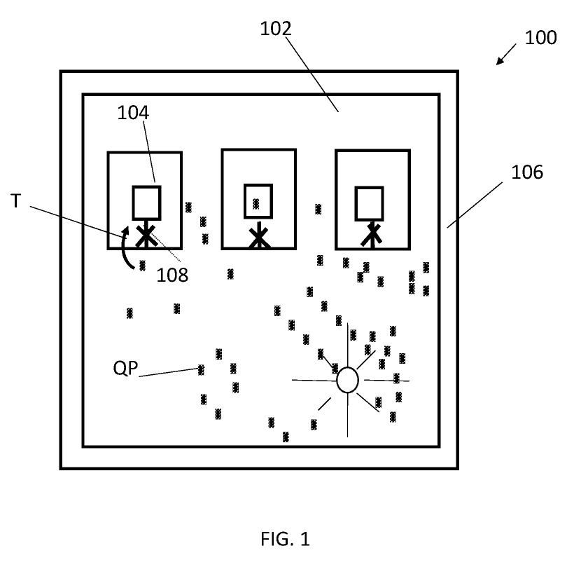

Referring now to FIG. 1, a device 100 constructed as a multiqubit chip or the like includes a superconducting ground plane 102 and a plurality of qubit circuits 104 on the ground plane 102. The device 100 may include other elements that are not shown for brevity such as capacitors, resonators, and other elements of a superconducting qubit device.

The qubit circuits 104 is formed of superconducting materials such as aluminum and may include additional thin film materials and multiple substrates, and/or other device circuitry for the measurement and control of electrical signals.

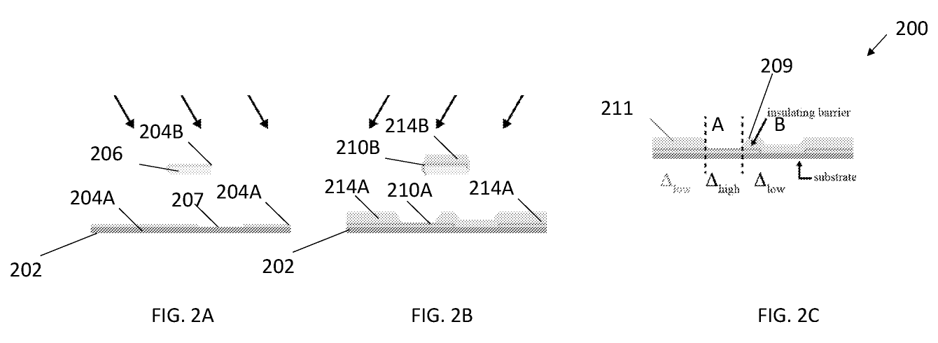

The ground plane 102 and Josephson junction 108 of the qubit circuit 104, is deposited on a substrate 106, and is used in superconducting qubits of the qubit circuits 104 disposed on the substrate 106. The Josephson junction 108 acts as a superconducting tunnel junction, and may include a barrier, for example, thin layer of insulator, transmissive material, or a quantum point contact between two superconductor layers, for example, shown in FIGS. 2A-2C. In particular, if the lower gap electrode is connected to a superconducting film that has quasiparticles, the quasiparticle tunneling will be mitigated as compared to the higher gap electrode being connected to the film with quasiparticles.

As shown in FIG. 1, a source of ionizing radiation results in the production of quasiparticles (QPs) in the superconducting thin film of the circuitry of the chip, which diffuse in the ground plane 102 and cause unwanted qubit decoherence upon quasiparticle tunneling (T). Individual qubit errors can occur if a quasiparticle tunnels across the Josephson junction 108 and causes a relaxation or excitation transition of the qubit’s state. If an individual qubit is susceptible to quasiparticle tunneling, then ionizing radiation impacts may cause correlated, or simultaneous, errors of multiple qubits.

FIGS. 2A-2C depict an example Josephson junction film deposition process 200, in accordance with the present disclosure. The process 200 can mitigate the correlated errors of superconducting qubits that may originate from energy deposited by ionizing radiation shown in FIG. 1.

As shown in FIG. 2A, a first deposited film for a superconducting electrode of a Josephson junction 200 is formed. In particular, a metallic thin film 204A is formed on a substrate 202. In some embodiments, the substrate 202 comprises silicon, sapphire, or other materials known for forming a superconducting qubit device substrate. In some embodiments, the first film 204A comprises aluminum. However, other embodiments may include different or additional materials having superconducting gap engineering properties.

In some embodiments, the first deposited film 204A is relatively thin, for example, 10nm but not limited thereto, as compared to a second deposited film 214A shown in FIG. 2B. The film 204A can be deposited on the substrate 202 using a thin-film photolithographic technique such as a Niemeyer-Dolan bridge, Manhattan, or free-standing shadow mask evaporation process but not limited thereto. Here, a bridge shadow mask 206 is positioned above a portion of the substrate 202 so that a gap 207 is formed between deposited portions of the film 204A. The shadow mask 206 may be formed of electron-beam sensitive polymers but not limited thereto. In doing so, a source of aluminum or the like can be angle-evaporated onto the substrate 202. In some embodiments, the junction as described may not be limited to having two electrodes, or terminals, and may have 3, 4, or more terminals which may affect, or function as, quasiparticle blocking, trapping, or electrical properties of the circuitry.

As shown in FIG. 2B, an oxide layer 210A and a second deposited film 214A for a second superconducting electrode of the Josephson junction 200 are formed. The second film 214A comprises aluminum. However, other embodiments may include different or additional materials having superconducting gap engineering properties.

In some embodiments, the second deposited film 214A has a relatively larger thickness than the relatively thin first film 204A, for example, 150nm but not limited thereto. The film thicknesses are provided for achieving a desired energy gap difference. Due to the thickness differential, the first film 204A provides for a larger superconducting energy gap than that of the second film 214B. In some embodiments, the difference of electrode gap energies should at least exceed the characteristic kinetic energy of the quasiparticles which might range from 0.1 K to 1 K (energy quantified by a temperature). As shown in the figures and described herein, a desirable performance is expected if the electrodes have a gap energy difference that exceeds the energy of the qubit transition which typically ranges from 3 - 7 GHz (energy quantified by frequency), but not limited thereto. Other ranges, e.g., 0-100 GHZ may equally apply depending on the application.

FIG. 2C illustrates a junction 200 formed by the film deposition process illustrated in FIGS. 2A and 2B. As shown, the junction 200 has a high-energy gap region (A) at a first side of a barrier 209 and a low-energy gap region (B) at a second side of the barrier 209, collectively referred to as an asymmetric junction. In some embodiments, an additional low-gap region 211 is formed by the parasitic junction that may cause quasiparticle trapping effects to further suppress tunneling, which is distinguished from blocking, and not trapping, quasiparticles at the junction. In some embodiments, similar to FIG. 1, the resulting device can include a superconducting ground plane. The ground plane can be above the substrate 202, and the second electrode formed from the second deposited film 214A can be a lower gap electrode that is galvanically connected to the ground plane. Since ionizing radiation might produce a larger quantity of quasiparticles in the larger electrode (for example, the ground plane in a single-ended qubit design but not limited thereto), a device constructed according to the method might most effectively reduce quasiparticle-induced errors if the lower-gap electrode is galvanically connected to the larger part of the surrounding circuit or the part of the surrounding circuit that has lesser trapping effect.

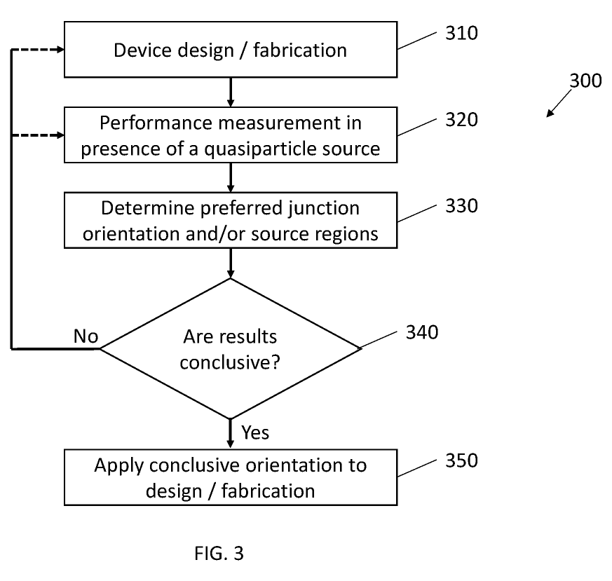

A quasiparticle blocking method, in accordance with some embodiments, may be performed by the junction 200 described in FIGS. 2A-2C. The method can be applied to a single asymmetric junction, and can be replicated for arrays of qubits, or other superconducting circuitry. In the method, a first layer of film 204A is deposited on a first region of a substrate 202. The first layer 204A may be formed of Al or other superconducting material, such as Niobium (Nb), Tantalum (Ta), Titanium Nitride (TiN), lead (Pb), but not limited thereto. The first layer of film 204A is constructed and arranged for forming a first electrode for superconducting qubits. The formed first electrode has a first thickness, height, or related dimensions for example, 10nm relative to the substrate surface, resulting in a first superconducting energy gap. A barrier, for example, an insulating layer, is deposited on the first layer of film 204A. The insulating layer 209 may be formed of AlOx or related material known for forming Josephson junctions. A second layer of film 214A is deposited on a second region of the substrate. The second layer 214A may be formed of Al or other superconducting material, such as Niobium (Nb), Tantalum (Ta), Titanium Nitride (TiN), lead (Pb), but not limited thereto. The second layer of film is constructed and arranged for forming a second electrode for superconducting qubits. The first electrode has a second thickness, for example, 150nm relative to the substrate surface. The first deposited film is relatively thin, e.g., 10nm, as compared to the second deposited film resulting in a desired energy gap energy different, and more specifically, a larger superconducting energy gap at region (A) in FIG. 2C as compared to the second deposited film at region (B). An asymmetric junction can be formed from the application of the two films 204A and 214A of different thicknesses and different superconducting gap energies. In some embodiments, an asymmetric junction can be formed according to a two-step process. In doing so, at block 308, the superconducting gap energies of the junction electrodes formed by the films 204A, 214A, respectively can be varied to prevent quasiparticle tunneling through the junction barrier 209. In varying the superconducting gap energies of the junction electrodes, a fabrication process can be controlled for a desired outcome, in particular, by performing the iterative steps of device design, fabrication (e.g., step 310 of FIG. 3), and measurement (e.g., step 320 of FIG. 3). An asymmetric junction can be oriented according to a technique described in embodiments herein such that the electrode that generally contains the most quasiparticles is the lower gap energy electrode at the low-gap region (B) at a second side of the barrier 209. The superconducting gap energy difference across the junction is preferably greater than the energy difference between the qubit states, or the relevant energy difference related to the error mechanism mediating quasiparticle tunneling. Here qubit transition frequency (e.g., 3-10 GHz for transmon qubits typically, and from DC to the frequencies limited by the gap energies of superconductors) of the superconducting circuit is provided so that quasiparticle-induced qubit transitions are suppressed compared a symmetric gap junction construction. In some embodiments, the junction of the superconducting circuitry is an asymmetric junction that functions as an electrical component for the construction of the circuit itself, e.g. it characteristically supports a nonzero phase difference of the superconducting order parameters across the electrodes of the junction over a range of energies that do not excess that of the superconducting gap energy itself.

In orienting the junction, specific design choices can be provided to which thin film the electrodes may connect. Examples are provided above, but not limited thereto. For example, an asymmetric junction orientation may be provided in the presence of intentional or unintentional quasiparticle trapping effects. In another example, quasiparticle trapping may be implemented in one region, e.g., the ground plane, so that the other region is a significant source of quasiparticles, whereby the junction can be oriented accordingly. The orientation may be determined by design and fabrication, which in turn determine which junction electrodes have a low/high gap. These design and fabrication choices are chosen to suppress quasiparticle tunneling from whichever thin films on the device are considered to be a source of quasiparticles. For example, if the ground plane is the source of quasiparticles, then one would design and fabricate the device so that the lower gap electrode connects to the ground plane (instead of the higher gap electrode connecting to the ground plane). In another example, a capacitance island may be connected to the lower gap electrode, the island may have a greater source of quasiparticles than a ground plane.

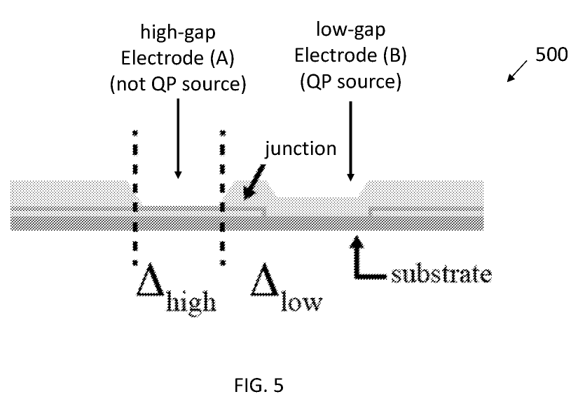

Different techniques may be applied to determine a preferred junction orientation (step 330 of FIG. 3) with respect to establishing a controlled source of quasiparticles in one region relative to other energy-gap regions, e.g., region (A) vs. region (B) shown in FIG. 5. In some embodiments, a procedure, e.g., method 300 of FIG. 3, may include fabricating (step 310) a device with one or multiple e.g., 2-50 qubits (or superconductive circuits) with subgroups of qubits, each subgroup having a specified junction orientation. While under test, the device, e.g., shown in FIG. 1, is exposed to a quasiparticle source, such as ionizing radiation from a manufactured source (Cs-137, Co-60, etc.), natural background ionizing radiation, non-ionizing radiation from ionizing radiation such as that emitted by fluorescence, phosphorescence, or Cherenkov radiation, mechanical impulses, strain relaxation, quasiparticle or phonon injection, quasiparticle or phonon generation by a voltage biased junction, a blackbody emission lamp, infrared or visible light illumination, or laser irradiation but not limited thereto. Device performance (e.g. error probability, energy-relaxation rates, state-leakage probability, and/or inferred quantities such as an error scaling parameter Λ) can be determined by monitoring errors (or quantities that errors are correlated to, e.g. energy-relaxation, energy-excitation, state-leakage, absorption linewidth, decoherence, charge or flux offset stability, tunneling current, switching probability, or Joule heating) of individual components and determine the rate of correlated error events among qubits, superconducting circuitry (or representative circuits, sensors, or detectors). The error events may be temporally and/or spatially correlated. Temporally correlated errors may exhibit a correlation timescale related to the phenomena of the quasiparticle generating source and/or the dynamics of quasiparticle trapping, recombination, or transport, e.g. qubits that do not have junctions of a preferred orientation may exhibit excess errors for 0-10 ms after an impact of ionizing radiation to the device substrate. Spatially correlated errors may exhibit a correlation length related to the phenomena of the quasiparticle generating source and/or the dynamics of quasiparticle trapping, recombination, or transport, e.g. qubits that do not have junctions of a preferred orientation may concurrently (for example, within 0-10 ms) exhibit excess errors after an impact of ionizing radiation to the device substrate. The preferred junction orientation might be inferred from these data, such as the junction orientation represented by qubits (or subgroups of qubits) that have a less significant participation in, and/or occurrence rate of, correlated error events.

In some embodiments, device design, fabrication methods, and operation (steps 310-330) may be adjusted, or optimized, with respect to process control parameters such as the superconducting materials used and parameters that influence their superconducting gap energies such as film thickness, oxygen doping, and strain. Aspects of the circuit construction may affect phonon or quasiparticle transport from certain regions, which may result in a preferred asymmetric junction orientation. At decision diamond 340, if a determination is made that the results are inconclusive, then the method 300 returns to step 310 or 320. Otherwise, the method 300 proceeds to step 350, where the orientation is applied to the design or fabrication.

Additional process testing may include monitoring of quasiparticle tunneling via parity-switching rates of individual components, monitoring of charge-offset of individual components to determine when correlated error events might occur, inclusion of other co-located sensors and/or detectors (e.g. transition-edge sensors, microwave kinetic inductance detectors, nanowires, scintillators) to improve the identification of when quasiparticle sources are present, e.g., step 330 in FIG. 3. For example, a detector can inform of a radiation impact to the device which would affect errors for quasiparticle-sensitive circuits. Such sensors and/or detectors may be designed and fabricated in place of one or more qubits (or other superconducting circuit elements) to determine quasiparticle sources external to the quantum computing device, quasiparticle sources regions of the device, and/or quasiparticle source external to the junction electrodes, and/or a preferred junction orientation. Other features may include in situ variation of circuit parameters such as transition energies, transition matrix elements, possibly by using charge or flux bias or driving, and which may modify device susceptibility to quasiparticle, a temperature variation to elucidate superconducting gap energies and gap energy differences among regions of the device, an in situ variation of circuit transition frequencies (energies) to deduce the energetics of the asymmetric junction, by way of a circuit’s frequency-dependent sensitivity to quasiparticle tunneling, measurements of other circuits, such as fluxonium qubits, to differentiate quasiparticle-induced error rates from other error sources, e.g. by comparison of error rates at flux biases which have variable levels quasiparticle sensitivity, or infer the characteristic thermal energy of the quasiparticles. Features may also include in situ modification of the governing quasiparticle dynamics, such as modified trapping rates, or the spatial distribution thereof, due to the presence of superconducting vortices from an applied magnetic field. Additional process testing may include but not limited to other metrology, for process control such as DC transport measurements of tunnel junctions to determine superconducting gap energies and their differences, or atomic force microscopic of superconducting thin films to determine process control parameters such film thickness.

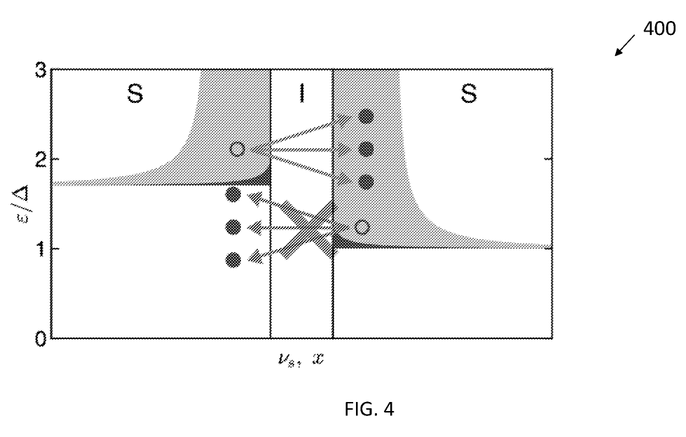

As previously described, the superconducting gap energy difference due to the differences in the first electrode and second electrode affects the rate of quasiparticle tunneling. For example, as shown in FIG. 4, there are different quasiparticle tunneling rates for tunneling transitions from the left-to-right and right-to-left electrodes through an insulating junction barrier (I) providing for junction asymmetry, illustrated in the plot showing energy versus density-of-states. The quasiparticle tunneling rates can be determined from the available density-of-states for each type of tunneling transition. Accordingly, a spatial profile of the superconducting gap, or gap engineering, can be designed to control quasiparticles in superconducting devices. In aluminum films, their thickness modulates the gap. Therefore, the fabrication of Josephson junctions, which relies on overlapping a thicker film on top of a thinner one, results in gap-engineered devices. In some embodiments, the films 204A, 214A can have similar densities, where a qubit's excited state population is lower but its relaxation rate higher than when the quasiparticles are confined, for example, shown in FIG. 4. The quasiparticle transitions which relax the qubit state are shown as an increase of the quasiparticle energy across the barrier. Similarly, the quasiparticle transitions which excite the qubit state are shown as a decrease of the quasiparticle energy across the barrier. In addition, there is a quasiparticle tunneling process that does not induce a transition between states of the qubit.

Referring again to FIG. 4, shown are quasiparticles that tunnel from the right electrodes to the left electrode do not occur since there are no available quasiparticle states at the relevant energy for each of these processes.

As previously described, the superconducting gap energy difference due to the differences in the first electrode and second electrode affects the rate of quasiparticle tunneling. Quasiparticle tunneling rates can also depend on factors in addition to the superconducting gap energy at each electrode such as the qubit Josephson energy and charging energy and the effective quasiparticle temperature (or energy distribution).

As described above, some embodiments include a normalized rate of a quasiparticle tunneling process with respect to a junction gap asymmetry for right-to-left tunneling transitions and left-to-right tunneling transitions, respectively. For typical qubit parameters, the tunneling rates for the right-to-left electrode can be suppressed for a gap asymmetry ratio less than 1.0, namely, where if the qubit transition energy is less than the gap difference, tunneling rates are suppressed, blocked, or otherwise having a reduced tunneling rate from the right-to-left electrode as compared to the left-to-right electrode. For this superconducting gap engineering method, the gap energy difference only needs to exceed the energy of the qubit transition and the energy of quasiparticles in the lower gap electrode. The rate of quasiparticle tunneling from the low gap electrode to the high gap electrode is zero if the superconducting gap difference is sufficiently large, for example, greater than the qubit frequency. The tunneling rates for the left-to-right electrodes are not suppressed which motivates a specific orientation of the junction to mitigate multi-qubit correlated errors such that the lower-gap electrode connects to the thin film that is the predominant source of quasiparticles. An example of an asymmetric junction 500 is shown in FIG. 5, which is oriented for optimal quasiparticle blocking at the asymmetric junction 500, such that the higher-gap electrode is not a source of quasiparticles.

A region of a quantum device, or more specifically, a region at or near the substrate shown in FIG. 5 may be a significant source of quasiparticles if the error probability (i.e. energy-relaxation rate) of multiple components connected to the region exhibit occurrences of temporally correlated (~0-10 ms) and/or spatially correlated (multi-qubit, with a length-scale that may relate to the quasiparticle generating source) changes (>10% change and/or > 1 error per observation time (such as a 10 ns duration or longer) that exceeds a one-tailed 95% confidence interval expected for an error count per observation time for error uncorrelated to the quasiparticle source under test). In other embodiments, a significant source of quasiparticles may be determined if the quasiparticle density exceeds a lower threshold within, but not limit to, the range 10⁻¹⁰-10⁻⁶ quasiparticles per Cooper pairs in the region near the junction electrodes, or if an excess energy-relaxation rate is observed within the equivalent of this quasiparticle density range.

In some embodiments, a quantum computer can use multiple asymmetric junctions in the electrode construction to reduce quasiparticle tunneling in both directions. For example, one direction corresponds to tunneling from the ground plane across the junctions to the capacitor, while the other direction corresponds to tunneling from the capacitor across the junctions to the ground plane.

The use of two junctions as described in embodiments above can achieve the blocking effect in both of these directions if the lower gap electrode of one junction connects to the ground plane while the lower gap electrode of the other junction connects to the capacitor thin film. The high gap electrodes of the two junctions are connected. Quasiparticles are blocked from traveling from ground plane to capacitor (and vice versa) because they cannot tunnel onto the high gap electrodes. The volume of the high gap electrodes is preferably small (compared to the volume of the device substrate) so that the high gap electrode is unlikely to be an initial source of quasiparticles from phonons caused by ionizing radiation or other sources. In some embodiments, the foregoing technique can be used for a “floating”, or differential, circuit which has two capacitors and does not connect to the ground plane.

Although the foregoing describes qubit-based applications, the inventive concept may be applied to applications that do not include units of quantum information that may nevertheless employ the use of asymmetric junctions, for example, Josephson junctions or the like, for reducing correlated errors. Embodiments above recite applications where the units of quantum information include qubits. However, other units of quantum information may include qutrits and/or qudits, but not limited thereto.

The mitigation of quasiparticle tunneling that is achieved by oriented asymmetric junctions may improve the performance of any superconducting circuitry (and not exclusively for the processing and control of quantum information). Superconducting tunnel junctions (such as Josephson junctions) are used ubiquitously in superconducting circuitry for broad applications related to information processing, signal processing and detection technologies. Examples of these technologies may relate to superconducting logic and signal processing including rapid single flux quantum (RSFQ) and quantum flux parametron (QFP), as well as technologies within the field of superconducting circuits related to quantum information processing, such as circuit quantum electrodynamics (circuit QED), and also including applications such as amplification, parametric coupling, sensing and detection (e.g. Josephson parametric amplifiers, flux-tunable coupling elements, and SQUID magnetometers).

Within the field of circuit QED, applications to which the inventive concepts may apply may include devices which can be used for, or in conjunction with, quantum information processing. For example, but not limited to, quantum coherent circuits: charge qubits, Cooper-pair box, transmon, flux qubits, fluxonium, quarton, bifluxon, zero-pi, cos 2φ, inductively shunted transmon, phase qubits, etc., auxiliary/ancilla circuits (e.g. transmon, fluxonium), e.g. for bosonic encoding of quantum information, parity-check measurements, and coupling elements, resonators, e.g. junction arrays for qubit readout, Josephson parametric amplifiers, such as an Josephson traveling wave parametric amplifier (JTWPA), Josephson bifurcation amplifier (JBA), SNAIL parametric amplifier (SPA), (see SNAIL below), Josephson parametric couplers (JPC), and Josephson junction-based circulators or devices for non-reciprocity. The inventive concepts may apply to circuit primitives such as a superconducting quantum interference device (SQUID), including DC and RF SQUIDs, symmetric threaded SQUIDs (ATS), Josephson junction arrays, superconducting Nonlinear Asymmetric Inductive eLements (SNAIL), and the like. Detection and sensing technologies may include but not be limited to kinetic inductance detectors (KIDs), including lumped element microwave kinetic inductance detector (LEKID), charge sensors, such as the Cooper-pair transistor (CPT) and offset-charge sensitive (OCS) transmon, and/or power detection/calibration: open-transmission line (OTL) qubits.

Additional applications of asymmetric junction electrodes oriented for optimized circuit performance may include hybrid technologies, such as quantum acoustodynamics (surface acoustic wave resonators, bulk acoustic wave resonators), as well as hybrid superconducting-semiconducting systems such as spin qubits, semiconductor quantum dots, and parity-based qubits (Andreev qubits, Majorana qubits). Oriented asymmetric junctions may improve these devices by the mitigation of phonon generation that would otherwise result from tunneling of quasiparticles. In these applications, or others, the application of asymmetric junction electrodes oriented for optimized circuit performance may have an orientation such that the lower gap electrode has a greater external source of quasiparticles, or a different type of localized excitation from a ground state. Such applications may include electrodes, or other regions that are a part of, or adjacent to, the junction barrier such that there is a dissimilar energy potential forming an asymmetric junction.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

While the invention has been shown and described with reference to specific embodiments, it should be understood by those skilled in the art that various changes in form and detail may be made therein without departing from the scope of the invention.

What is claimed is:

1. An arrangement of superconductive circuitry in a quantum computing device, the computational accuracy of which is degraded by quasiparticle-induced spatially and/or temporally correlated errors, each superconductive circuit in the arrangement comprising:
a first electrode deposited on a substrate, the first electrode constructed and arranged to provide a first superconducting gap energy at a first region of the substrate;
a second electrode deposited on the substrate, the second electrode constructed and arranged to provide a second superconducting gap energy at a second region of the substrate that is less than the first superconducting gap energy at the first region;
a barrier that separates the first region and the second region; and
an asymmetric junction at the barrier, the asymmetric junction formed by an energy gap difference between the first superconducting gap energy of the first electrode and the second superconducting gap energy of the second electrode, the asymmetric junction oriented so that the second electrode is a lower gap electrode having a larger external source of quasiparticles than the first electrode that can otherwise induce correlated errors to block or reduce a first tunneling rate of quasiparticles from the second region through the barrier to the first region as compared to a second tunneling rate of quasiparticles from the first region through the barrier to the second region.

2. The arrangement of superconductive circuitry of claim 1, wherein the asymmetric junction operates as a Josephson junction to prevent quasiparticle tunneling related to a spatiotemporally correlated error burst at the quantum computing device.

3. The arrangement of superconductive circuitry of claim 1, further comprising a ground plane above the substrate, wherein the second electrode includes a lower gap electrode that is galvanically connected to the ground plane.

4. The arrangement of superconductive circuitry of claim 1, further comprising a capacitance island above the substrate, wherein the second electrode includes a lower gap electrode that is connected to the capacitance island.

5. The arrangement of superconductive circuitry of claim 1, further comprising multiple asymmetric junctions oriented to prevent the higher-gap electrode from being a greater source of quasiparticles and thereby reduce tunneling across the junction.

6. The arrangement of superconductive circuitry of claim 1, wherein each superconductive circuit is constructed and arranged as a qubit.

7. The arrangement of superconductive circuitry of claim 1, wherein the superconducting energy gap is controlled by a thickness of the first and/or second electrode, which is controlled by a deposition rate or deposition duration.

8. The arrangement of superconductive circuitry of claim 1, wherein a superconducting gap energy difference between the first superconducting gap energy and the second superconducting gap energy is greater than the energy of a qubit transition at the barrier.

9. The arrangement of superconductive circuitry of claim 1, wherein the first and second electrodes are formed of different superconducting materials.

10. The arrangement of superconductive circuitry of claim 1, wherein a gap energy difference between the first and second electrodes is greater than an energy of the quasiparticles at the asymmetric junction.

11. The arrangement of superconductive circuitry of claim 1, wherein the first electrode has a first thickness that is less than a second thickness of the second electrode.

12. A quantum computing device, the computational accuracy of which is degraded by quasiparticle-induced spatiotemporally correlated qubit errors, comprising :
a substrate;
an arrangement of superconductive circuitry, wherein each unit of quantum information comprises:
a first electrode on the substrate, the first electrode constructed and arranged to provide a first superconducting gap energy at a first region of the substrate;
a second electrode on the substrate, the second electrode constructed and arranged to provide a second superconducting gap energy at a second region of the substrate that is less than the first superconducting gap energy at the first region;
a barrier that separates the first region and the second region; and
an asymmetric junction at the barrier, the asymmetric junction formed by an energy gap difference between the first superconducting gap energy of the first electrode and the second superconducting gap energy of the second electrode, the asymmetric junction oriented so that the second electrode is a lower gap electrode having a larger external source of quasiparticles than the first electrode that can otherwise induce correlated errors to block or reduce a first tunneling rate of quasiparticles from the second region through the barrier to the first region as compared to a second tunneling rate of quasiparticles from the first region through the barrier to the second region.

13. The quantum computing device of claim 12, wherein the asymmetric junction operates as a Josephson junction to prevent quasiparticle tunneling related to a spatiotemporally correlated error burst at the quantum computing device.

14. The quantum computing device of claim 12, further comprising a capacitance island above the substrate, wherein the second electrode includes a lower gap electrode that is connected to the capacitance island.

15. The quantum computing device of claim 12, further comprising multiple asymmetric junctions oriented to prevent the higher-gap electrode from being a greater source of quasiparticles and thereby reduce tunneling across the junction.

16. The quantum computing device of claim 12, wherein a superconducting gap energy difference between the first superconducting gap energy and the second superconducting gap energy is greater than the energy of a qubit transition at the barrier.

17. The quantum computing device of claim 12, wherein the first and second electrodes are formed of different superconducting materials.

18. The quantum computing device of claim 10, wherein a superconducting gap energy difference between the first superconducting gap energy and the second superconducting gap energy is greater than the energy of a qubit transition at the barrier.

19. A method for operating a quantum computing device, the computational accuracy of which is degraded by quasiparticle-induced spatiotemporally correlated qubit errors, comprising:
arranging superconductive circuitry on a substrate, wherein for each superconductive circuit, the method comprises:
depositing a first electrode on the substrate, the first electrode constructed and arranged to provide a first superconducting gap energy at a first region of the substrate;
depositing a second electrode on the substrate, the second electrode constructed and arranged to provide a second superconducting gap energy at a second region of the substrate that is less than the first superconducting gap energy at the first region;
forming a barrier that separates the first region and the second region;
forming the asymmetric junction formed by an energy gap difference between the first superconducting gap energy of the first electrode and the second superconducting gap energy of the second electrode; and
orienting the asymmetric junction so that the second electrode is a lower gap electrode having a larger external source of quasiparticles than the first electrode that can otherwise induce correlated errors to block or reduce a first tunneling rate of quasiparticles from the second region through the barrier to the first region as compared to a second tunneling rate of quasiparticles from the first region through the barrier to the second region.

20. The method of claim 1, wherein the asymmetric junction operates as a Josephson junction to prevent quasiparticle tunneling related to a spatiotemporally correlated error burst at the quantum computing device.
